(19) United States
(12) Patent Application Publication
(10) Pub. No.: US 2005/0040856 A1
(43) Pub. Date: Feb. 24, 2005

(54) Domino circuitry compatible static latch

(76) Inventors: Ravindraraj Ramaraju, Round Rock, TX (US); Jeremiah T. Palmer, Round Rock, TX (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 10/646,081

(22) Filed: Aug. 22, 2003

(51) Int. Cl. H03K 19/00

(52) U.S. Cl. 326/93

(57) ABSTRACT

A circuit provides latched data in a domino circuit environment. The circuit receives a pair of input signals that are either in complementary logic states, which is data, or in the same logic state, which is the reset condition. The circuit responds to the complementary logic states by providing intermediate signals and output signals in corresponding complementary logic states. The intermediate logic states are latched by cross-coupled clocked inverters prior to the pair of signals switching from data to reset. The intermediate signals are thus latched in the complementary logic states that correspond to data even after the pair of input signals have returned to reset. The output signals are also thus provided in complementary logic states that correspond to data prior to the input signals being reset.

### BACKGROUND

1. Field of the Invention

The present invention relates to digital circuitry, and, more particularly, to domino-compatible latching circuitry.

2. Description of the Related Art

In high performance logic circuits, domino style circuitry is sometimes used, with domino driven static logic being a common configuration. This configuration includes ‘dynamic’ and ‘static’ blocks. The ‘dynamic’ blocks include transistors which are first pre-charged and then perform logical functions during an evaluation phase. When these functions require more than a single clock/(evaluation) phase to complete, a latch must be used to facilitate signals crossing the timing boundary at the end of the phase. Due to domino circuitry's evaluate/pre-charge behavior, domino circuitry cannot be driven by static logic and a domino compatible latch must be used. However, domino latches include characteristics which must be accounted for in comparison to static latches. Therefore, there is a need for an efficient static latch with domino compatible outputs, reduced timing complexity, and increased noise immunity.

### BRIEF DESCRIPTION OF THE DRAWINGS

The present invention may be better understood, and its numerous objects, features, and advantages made apparent to those skilled in the art, by referencing the accompanying drawings. The use of the same reference symbols in different drawings indicates similar or identical items.

FIG. 1 is a block diagram illustrating an exemplary domino-compatible static latch and surrounding circuitry.

FIG. 2 is a circuit diagram illustrating an exemplary domino-compatible static latch.

FIG. 3 is a flow diagram illustrating functionality of the domino-compatible static latch of FIG. 2.

FIG. 4 is a timing diagram illustrating the operation of the domino-compatible static latch of FIG. 2.

FIG. 5 is a circuit diagram illustrating another exemplary domino-compatible static latch.

### DETAILED DESCRIPTION OF THE PREFERRED EMBODIMENT(S)

The following discussion is intended to provide a detailed description of at least one example of the invention and should not be taken to be limiting of the invention itself. Rather, any number of variations may fall within the scope of the invention which is properly defined in the claims following this description.

FIG. 1 shows an exemplary circuit 100. Circuit 100 is representative of any type of information processing circuit or system which includes domino-type circuitry or other circuitry which operates in a manner similar to certain features of domino circuitry. As illustrated, circuit 100 includes domino-compatible complementary output circuit 110, domino-output static latch 120 and domino logic 130. Although only a partial set of domino circuitry is shown, circuit 100 would typically include several layers of domino circuitry separated by sets of latches. In the illustrated case, domino circuitry 110 feeds data signals to a set of latches (e.g., latch 120 among other latches) which in turn feed domino circuitry 130, which may in turn feed another set of latches. The latches hold data resulting from each domino circuit for further evaluation during a subsequent clock cycle.

Circuit 110 is any type of domino type or domino compatible complementary output circuit such as domino combinational logic. Circuit 110 may be another type of circuit which includes outputs which are precharged to certain values (e.g., low, zero volts, or zero bit values) and which provides complementary outputs. For example, circuit 110 may be a memory such as an SRAM or a DRAM. Circuit 110 provides domino complementary signals to domino-output static latch 120.

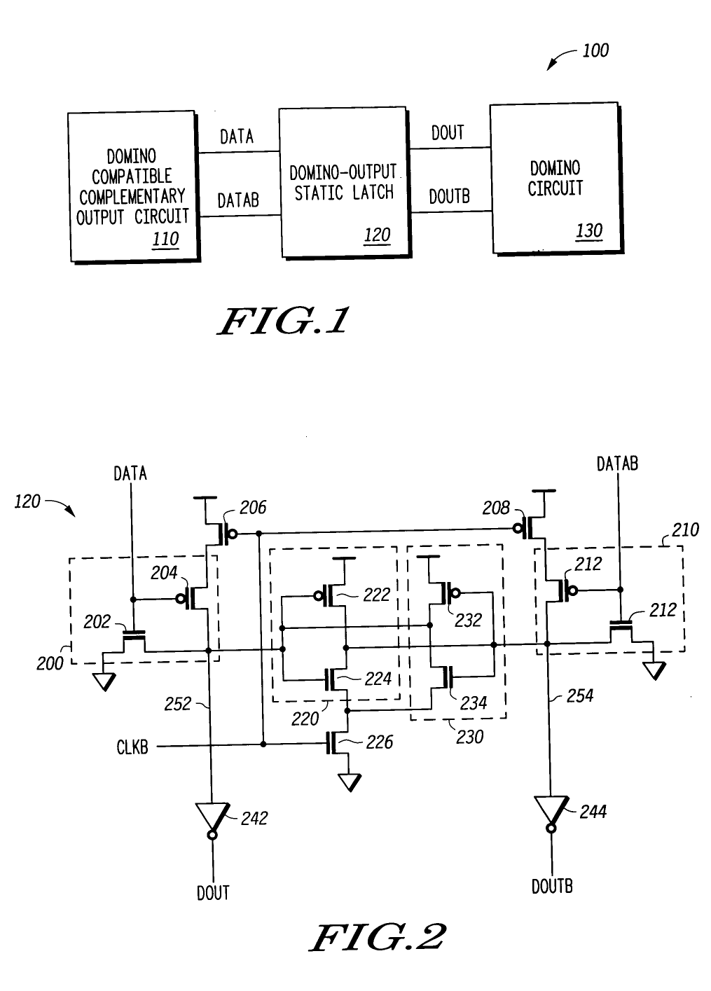

Domino-output static latch 120 is representative of a latch which is appropriate for use in a domino-based circuit such as circuit 110. Examples of such latches are discussed below with reference to FIGS. 2 and 5. Latch 120 is coupled to receive complementary inputs DATA and DATAB from circuit 110. Domino-output static latch 120 is coupled to provide complementary outputs DOUT and DOUTB to domino circuit 130.

Domino circuit 130 is representative of any type of circuit which receives domino-type input signals and processes such signals accordingly. Domino circuitry typically operates on a different clock or clock phase than previous stage domino circuitry. For example, circuit 110 may operate using a first phase of a system clock CLK, and circuit 130 may operate using a second phase or even a complementary clock CLKB. In this way, circuit 130 may be evaluating data received from circuit 110 via latch 120 while circuit 110 is in a reset (e.g., precharge) state, as described more fully below.

FIG. 2 is a circuit diagram illustrating an exemplary domino-compatible static latch 120. Latch 120 includes multiple clock enabled inverters. For example, latch 120 includes clock enabled input inverters 200 and 210 which receive true and complement data inputs DATA and DATAB, respectively. Latch 120 also includes clock enabled cross-coupled inverters 220 and 230 which provide latch storage. Latch 120 also includes output inverters 242, 244 which provide true and complement data output signals DOUT and DOUTB, respectively.

As would be obvious to one of ordinary skill, true and complement data signal pairs DATA and DATAB, and DOUT and DOUTB, are complementary in a special sense commonly understood by designers of domino compatible circuitry (e.g., domino circuits and memories). For example, the mentioned signals are sometimes forced to the same value in a local signal precharge state. This can be seen in conventional domino circuits, and even in memory circuits where commonly referred to complementary bit lines are precharged to identical values. Thus, although typically referred to as being complementary in this field, such signals are not forced to be complementary at all times of circuit operation, but only as appropriate given the local signal requirements of the overall domino circuit design. For example, the mentioned data pairs are complementary during locally relevant data processing phases of operation of each signal pair, and may be forced to identical values (e.g., low or zero) during various other times such as precharge phases of operation.

Latch 120 receives data inputs DATA and DATAB via input inverters 200 and 210. Inverter 200 includes PMOS transistor 202 and NMOS transistor 204 coupled together in a CMOS inverter structure. Inverter 210 includes PMOS transistor 212 and NMOS transistor 214 coupled together in a CMOS inverter structure. The output of inverter 200 is coupled to the input of inverters 242 and 220 (discussed below), and the output of inverter 210 is coupled to the input of inverters 244 and 230 (discussed below).

Latch 120 includes cross-coupled inverters 220 and 230. Inverter 220 includes PMOS transistor 222 and NMOS transistor 224 coupled together in a CMOS inverter structure. Inverter 230 includes PMOS transistor 232 and NMOS transistor 234 coupled together in a CMOS inverter structure. The output of inverter 220 is coupled to the input of inverter 230, and the output of inverter 230 is coupled to the input of inverter 220.

As discussed above, latch 120 is clock enabled. For example, inverters 220 and 230 are clock enabled through clock enable transistor 226 which selectively couples NMOS transistors 224, 234 to ground under control of complementary clock signal CLKB. Latch 120 also includes pull-up output reset PMOS transistors 206 and 208 which respectively couple inverters 200 and 210 to V_{DD} under control of signal CLKB to enable input inverters 200, 210.

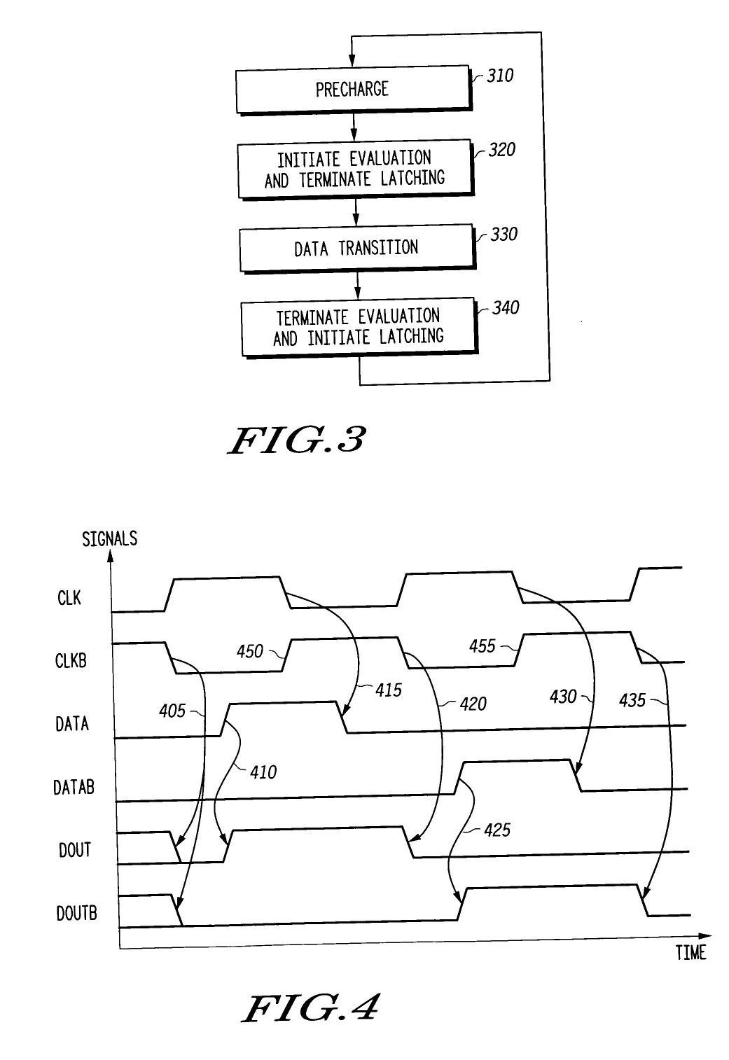

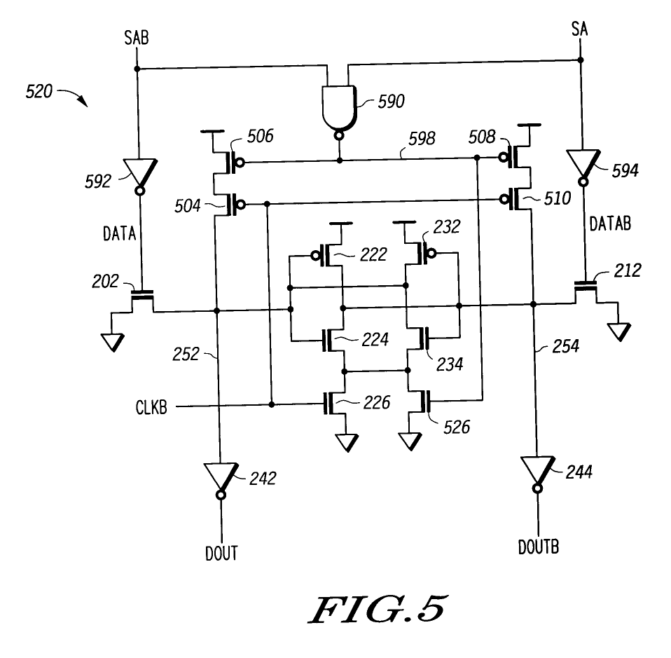

The operation of latch 120 will now be discussed with reference to FIGS. 3 and 4. FIG. 3 shows an operational flow of domino-compatible static latch 120, and FIG. 4 is a timing diagram illustrating the operation of domino-compatible static latch 120.

Upon power up, and each time the data clock CLK of circuit 100 transitions into a low state (and therefore complementary clock CLKB transitions into a high state, e.g., at times 450 and 455 shown in FIG. 4), latch 120 enters precharge state 310 as shown in FIG. 3. While in precharge state 310, the data signals DATA and DATAB input to latch 120 are held low by previous stage circuits (i.e., circuit 110) as a result of domino circuit design requirements which require that input signals are low. For example, a typical domino circuit would include clocked circuit elements for resetting output nodes to zero during precharge state 310 (e.g., during the low state of CLK). When latch 120 enters precharge state 310, its output signals DOUT and DOUTB are held in their current state until after termination of the precharge state.

When CLK transitions to a high state, latch 120 enters evaluation stage 320. As shown in FIG. 3, evaluation is initiated and latching is terminated during evaluation stage 320. For example, the cross-coupled inverters are disabled, and the latch outputs DOUT and DOUTB are forced low (see 405, 420 and 435 in FIG. 4) as a result of CLKB transitioning to a low state and the data inputs DATA and DATAB being low. The outputs both remain low until a data transition occurs. Because CLKB is low, output pull-up reset transistors 206, 208 are on, thereby enabling input inverters 200, 210. Latch 120 then awaits a data transition at data inputs DATA and DATAB.

After evaluation stage 320, a data transition may occur at data transition stage 330. Because complement data inputs are received, a data transition will be detected by latch 120 on one of the two data input signal lines. When a data transition occurs on one of the data inputs DATA or DATAB, the transition is passed through latch 120. For example, if DATA transitions from low to high, node 252 will transition to a low state, whereupon DOUT will transition to a high state, as illustrated at 410 in FIG. 4. If DATAB transitions from low to high, node 254 will transition to a low state, whereupon DOUTB will transition to a high state, as illustrated at 425 in FIG. 4.

After data transition stage 330, latch 120 terminates evaluation and initiates latching during latching stage 340 (FIG. 3). CLKB transitions to a high state (e.g., at 450 and 455), thereby enabling the cross-coupled inverters 220 and 230, and holding the current values of nodes 252 and 254, and therefore holding the current values of output signals DOUT and DOUTB. Because CLKB is high, output pull-up reset transistors 206, 208 are off, thereby disabling input inverters 200 and 210. This protects the stored value and prevents the output signals DOUT and DOUTB from being affected by new data transitions. A data input signal DATA or DATAB may then transition to a low state (e.g., at times 415 and 430 shown in FIG. 4) without affecting the data available to the next domino circuit block (e.g., domino circuit 130).

FIG. 5 shows another embodiment of a domino-circuitry-compatible static latch 520. Latch 520 includes input inverters 592, 594 coupled to receive differential input signals SA and SAB, and to provide differential data signals DATA and DATAB. DATA and DATAB are provided to the control terminals of transistors 202 and 212, respectively (e.g., instead of to inverters such as the input inverters 200 and 210 of FIG. 2). Latch 520 includes PMOS transistors 506 and 508. Transistor 506 has a first current handling terminal coupled to a first power rail (e.g., V_{DD}) and a second current handling terminal coupled to a first current handling terminal of transistor 504. Transistor 508 has a first current handling terminal coupled to a first power rail (e.g., V_{DD}) and a second current handling terminal coupled to a first current handling terminal of transistor 510. Each of transistors 506 and 508 have a control terminal (e.g., a gate) coupled to receive a control signal 598 from detector circuit 590. Detector circuit 590 is a NAND gate for detecting when the input signals SA and SAB become complementary, thereby selectively enabling the latch through transistors 506 and 508. Transistors 504 and 510 each include a control terminal coupled to a clock CLKB to perform a latch clocking function similar to that performed by transistors 206 and 208 of FIG. 2. The second current handling terminal of each of transistors 504 and 510 are coupled to output inverters 242 and 244. Transistor 226 is coupled similarly to the couplings shown in FIG. 2 and is triggered by the clock CLKB. Transistor 526 is coupled in parallel to transistor 226 and is triggered by control signal 598 instead of CLKB.

The exemplary latch of FIG. 5 is a self-timing, domino-compatible static latch which is capable of determining a differential between a bitline (SA) and a bitline bar (SAB) without any dependency on the falling edge of the clock. Thus, latching occurs earlier. For example, by providing, among other things, the detector circuit 590 and transistors 506, 508 and 526 as shown, latching occurs relatively quickly after the relevant transition on the bitlines with direct dependency on the clock. The latch of FIG. 5 can then reset the latch output to zero responsive to the rising edge of the clock.

The various gates represented herein may not be necessary in every embodiment. Other embodiments may use other types of gates to provide functionally equivalent logic. For example, detector circuit 590 need not be a NAND gate. Other embodiments may use an OR-gate-based detector and/or other logically equivalent circuitry, as is understood by those of ordinary skill in the art.

The above description is intended to describe at least one embodiment of the invention. The above description is not intended to define the scope of the invention. Rather, the scope of the invention is defined in the claims below. Thus, other embodiments of the invention include other variations, modifications, additions, and/or improvements to the above description.

For example, in one embodiment, a method for providing first and second output signals in response to first and second input signals includes a number of steps including providing the first and second input signals at complementary logic states, and in response thereto, providing first and second intermediate signals on first and second nodes at the complementary logics states. A first clocked inverter is provided having a signal input coupled to the first node, a signal output coupled to the second node, and a clock input, and a second clocked inverter is provided having a signal input coupled to the second node, a signal output coupled to the first node, and a clock input. The first and second input signals are provided at a predetermined one of the complementary logic states after providing the first and second input signals at the complementary logic states. Prior to providing the first and second input signals at the predetermined one of the complementary logic states, the clock inputs of the first and second clocked inverters are then enabled whereby the first and second intermediate signals at the complementary logic states are latched. The first and second output signals are then provided responsive to the first and second intermediate signals.

In a further embodiment, the first and second clocked inverters have second clock inputs, and the method further includes enabling the second clock inputs in response to providing the first and second input signals at the complementary logic states. In another further embodiment, the first and second clocked inverters are characterized as inverting only one of the complementary logic states when the clock inputs are disabled and inverting both complementary logic states when the clock inputs are enabled. In another further embodiment, the first and second intermediate signals are provided by third and fourth clocked inverters responsive to the first and second input signals. The third and fourth clocked inverters may be characterized as inverting only one of the complementary logic states when the clock inputs are disabled and inverting both complementary logic states when the clock inputs are enabled.

In another embodiment, a method of providing first and second output signals in response to first and second input signals includes various steps including providing the first and second input signals at complementary logic states, and responsive thereto, providing first and second intermediate signals on first and second nodes at the complementary logics states in. A first clocked inverter is provided having a signal input coupled to the first node, a signal output coupled to the second node, and a clock input, and a second clocked inverter is provided having a signal input coupled to the second node, a signal output coupled to the first node, and a clock input. The first and second input signals are provided at a predetermined one of the complementary logic states during a precharge phase. The clock inputs of the first and second clocked inverters are enabled in response to entering the precharge phase. The first and second output signals are then provided responsive to the first and second intermediate signals.

In a further embodiment, the first and second inverters have second clock inputs, and the method further includes the step of enabling the second clock inputs in response to providing the first and second input signals at the complementary logic states. In another further embodiment, the first and second intermediate signals are provided by third and fourth clocked inverters responsive to the first and second input signals. The third and fourth clocked inverters may be characterized as inverting only one of the complementary logic states when the clock inputs are disabled and inverting both logic states when the clock inputs are enabled.

In another embodiment, a circuit includes four clocked inverters. The first clocked inverter has a signal input for receiving a first input signal, a clock input responsive to a clock signal, and an output. The second clocked inverter has a signal input for receiving a second input signal, a clock input responsive to the clock signal, and an output. The third clocked inverter has a signal input coupled to the output of the first clocked inverter, a clock input responsive to the clock signal, and an output. The fourth clocked inverter has a signal input coupled to the output of the second clocked inverter, a clock input responsive to the clock signal, and an output. The output of the fourth clocked inverter is coupled to the input of the third clocked inverter, and the output of the third clocked inverter is coupled to the input of the fourth clocked inverter.

In a further embodiment, the circuit further includes first and second inverters. The first inverter has an input coupled to the output of the first clocked inverter and an output for providing a first output signal. The second inverter has an input coupled to the output of the second clocked inverter and an output for providing a second output signal.

In another further embodiment, the first clocked inverter of the circuit includes three transistors, possibly among others. The first transistor has a control electrode coupled for receiving the first input signal, a first current electrode coupled to a first power supply terminal, and a second current electrode. The second transistor has a control electrode coupled for receiving the first input signal, a first current electrode coupled to the second current electrode of the first transistor, and a second current electrode. The third transistor has a control electrode coupled to be responsive to the clock signal, a first current electrode coupled to the second current electrode of the second transistor, and a second current electrode coupled to a second power supply terminal.

In yet a further embodiment, the third clocked inverter includes three additional transistors. The fourth transistor has a control electrode coupled to the second current electrode of the first transistor, a first current electrode coupled to the second power supply terminal, and a second current electrode coupled to the output of the second clocked inverter. The fifth transistor has a control electrode coupled to the second current electrode of the first transistor, a first current electrode coupled to the second current electrode of the fourth transistor, and a second current electrode. The sixth transistor has a control electrode coupled to be responsive to the clock signal, a first current electrode coupled to the second current electrode of the fifth transistor, and a second current electrode coupled to the first power supply terminal. The third and fourth transistors may be, for example, P channel transistors.

In another further embodiment, the first clocked inverter of the circuit includes three transistors, possibly among others. The first transistor has a control input for receiving the first signal, a first current electrode coupled to a first power supply terminal, and a second current electrode coupled to the signal input of the third clocked inverter. The second transistor has a control input for receiving the clock signal, a first current electrode coupled to the second current electrode of the first transistor, and a second current electrode. The third transistor has a control electrode for receiving a control signal, a first current electrode coupled to the second current electrode of the second transistor, and a second current electrode coupled to a second power supply terminal.

In another embodiment, a circuit includes first and second inverting circuits and first and second clocked inverters. The first inverting circuit has a signal input for receiving a first input signal and an output. The second inverting circuit has a signal input for receiving a second input signal and an output. The first clocked inverter has a signal input coupled to the output of the first inverting circuit, a clock input responsive to a clock signal, and an output. The second clocked inverter has a signal input coupled to the output of the second inverting circuit, a clock input responsive to the clock signal, and an output.

In a further embodiment, the first clocked inverter of the circuit includes three transistors, possibly among others. The first transistor has a control electrode coupled to the output of the first inverting circuit, a first current electrode coupled to a first power supply terminal, and a second current electrode. The second transistor has a control electrode coupled to the output of the first inverting circuit, a first current electrode coupled to the second current electrode of the first transistor, and a second current electrode. The third transistor has a control electrode coupled to be responsive to the clock signal, a first current electrode coupled to the second current electrode of the second transistor, and a second current electrode coupled to a second power supply terminal.

In a further embodiment, the first inverting circuit is further characterized as having a clock input and further includes first, second and third transistors. The first transistor has a control electrode coupled for receiving the first input signal, a first current electrode coupled to a first power supply terminal, and a second current electrode. The second transistor has a control electrode coupled for receiving the first input signal, a first current electrode coupled to the second current electrode of the first transistor, and a second current electrode. The third transistor has a control electrode coupled to be responsive to the clock signal, a first current electrode coupled to the second current electrode of the second transistor, and a second current electrode coupled to a second power supply terminal.

In a further embodiment, the first inverting circuit of the circuit has a clock input, and further includes three transistors, possibly among others. The first transistor has a control electrode for receiving the first signal, a first current electrode coupled to a first power supply terminal, and a second current electrode coupled to the signal input of the first clocked inverter. The second transistor has a control input for receiving the clock signal, a first current electrode coupled to the second current electrode of the first transistor, and a second current electrode. The third transistor has a control electrode for receiving a control signal, a first current electrode coupled to the second current electrode of the second transistor, and a second current electrode coupled to a second power supply terminal.

In yet a further embodiment, the circuit further includes two inverters and a logic gate. The first inverter has an input for receiving a first primary input signal and an output for providing the first input signal, and the second inverter has an input for receiving a second primary input signal and an output for providing the second input signal. The logic gate has a first input for receiving the first primary input signal, a second input for receiving the second input signal, and an output for providing the control signal.

In another further embodiment, the circuit further includes two inverters. The first inverter has an input coupled to the output of the first clocked inverter and an output for providing a first output signal. The second inverter has an input coupled to the output of the second clocked inverter and an output for providing a second output signal.

In another embodiment, a circuit includes a domino-compatible latch. The latch includes complementary input inverters, input control circuitry, cross-coupled storage inverters and storage control circuitry. The input control circuitry is coupled to the input inverters to selectively configure the input inverters to prevent an output of each input inverter from making a first signal transition type. Each of the cross-coupled storage inverters has an input coupled to receive a signal from an output of one of the input inverters. The storage control circuitry is coupled to selectively configure the storage inverters to prevent an output of each storage inverter from making a second signal transition type. The first transition type may be, for example, a transition from low to high, and/or the second transition type may be, for example, a transition from high to low. Alternatively, the first transition type may be a transition from a first signal level corresponding to a first power rail value to a second signal level corresponding to a second power rail value, and the second transition type may be a transition from the second signal level to the first signal level.

In another embodiment, a latch includes a clocked input stage, a clocked storage stage, and an output stage. The clocked input stage is coupled to receive first and second complementary input signals. The clocked storage stage is coupled to the clocked input stage. The clocked storage stage includes two cross-coupled inverters. Each of the invertors are clocked. The output stage is coupled to the clocked storage stage to provide first and second complementary output signals.

Those skilled in the art will recognize that circuit elements in circuit diagrams and boundaries between logic blocks are merely illustrative, and that alternative embodiments may merge logic blocks or circuit elements or impose an alternate decomposition of functionality upon various logic blocks or circuit elements. Moreover, alternative embodiments may combine multiple instances of a particular component. For example, in the above described embodiment, a single latch 120 is shown, but various embodiments will often include multiple such latches or multi-bit latches. Also, the transistors of latch 120 have been logically partitioned merely to facilitate discussion of the functionality of same, and not to force artificial limitations on the scope of the claims which define the invention.

The foregoing components and devices are used herein as examples for sake of conceptual clarity. As for (nonexclusive) example, the depiction of a MOSFET transistor is representative of any type of switching device or circuit which may be appropriately employed to achieve the same or similar switching functionality. Consequently, as used herein the use of any specific exemplar herein is also intended to be representative of its class and the noninclusion of any specific devices in any exemplary lists herein should not be taken as indicating that limitation is desired.

The transistors described herein (whether bipolar, field effect, etc.) may be conceptualized as having a control terminal which controls the flow of current between a first current handling terminal and a second current handling terminal. An appropriate condition on the control terminal causes a current to flow from/to the first current handling terminal and to/from the second current handling terminal.

For example, in a bipolar NPN transistor, the first current handling terminal is the collector, the control terminal is the base, and the second current handling terminal is the emitter. A sufficient current into the base causes a collector-to-emitter current to flow. In a bipolar PNP transistor, the first current handling terminal is the emitter, the control terminal is the base, and the second current handling terminal is the collector. A current flowing between the base and emitter causes an emitter-to-collector current to flow.

Also, although field effect transistors (FETs) are frequently discussed as having a drain, a gate, and a source, in most such devices the drain is interchangeable with the source. This is because the layout and semiconductor processing of the transistor is frequently symmetrical. For an n-channel FET, the current handling terminal normally residing at the higher voltage is customarily called the drain. The current handling terminal normally residing at the lower voltage is customarily called the source. A sufficient voltage on the gate (relative to the source voltage) causes a current to therefore flow from the drain to the source. The source voltage referred to in n-channel FET device equations merely refers to which drain or source terminal has the lower voltage at any given point in time. For example, the “source” of the n-channel device of a bi-directional CMOS transfer gate depends on which side of the transfer gate is at the lower voltage. To reflect this symmetry of most n-channel FET devices, the control terminal may be deemed the gate, the first current handling terminal may be termed the “drain/source”, and the second current handling terminal may be termed the “source/drain”. Such a description is equally valid for a p-channel FET device, since the polarity between drain and source voltages, and the direction of current flow between drain and source, is not implied by such terminology. Alternatively, one current-handling terminal may arbitrarily deemed the “drain” and the other deemed the “source”, with an implicit understanding that the two are not distinct, but interchangeable.

Insulated gate FETs (IGFETs) are commonly referred to as MOSFET devices (which literally is an acronym for “Metal-Oxide-Semiconductor Field Effect Transistor”), even though the gate material may be polysilicon or some material other than metal, and the dielectric may be oxynitride, nitride, or some material other than an oxide. The use of such historical legacy terms as MOSFET should not be interpreted to literally specify a metal gate FET having an oxide dielectric unless the context indicates that such a restriction is intended.

Because the above detailed description is exemplary, when “one embodiment” is described, it is an exemplary embodiment. Accordingly, the use of the word “one” in this context is not intended to indicate that one and only one embodiment may have a described feature. Rather, many other embodiments may, and often do, have the described feature of the exemplary “one embodiment.” Thus, as used above, when the invention is described in the context of one embodiment, that one embodiment is one of many possible embodiments of the invention.

Notwithstanding the above caveat regarding the use of the words “one embodiment” in the detailed description, it will be understood by those within the art that if a specific number of an introduced claim element is intended in the below claims, such an intent will be explicitly recited in the claim, and in the absence of such recitation no such limitation is present or intended. For example, in the claims below, when a claim element is described as having “one” feature, it is intended that the element be limited to one and only one of the feature described. Furthermore, when a claim element is described in the claims below as including or comprising “a” feature, it is not intended that the element be limited to one and only one of the feature described. Rather, for example, the claim including “a” feature reads upon an apparatus or method including one or more of the feature in question. That is, because the apparatus or method in question includes a feature, the claim reads on the apparatus or method regardless of whether the apparatus or method includes another such similar feature. This use of the word “a” as a nonlimiting, introductory article to a feature of a claim is adopted herein by Applicants as being identical to the interpretation adopted by many courts in the past, notwithstanding any anomalous or precedential case law to the contrary that may be found. Similarly, when a claim element is described in the claims below as including or comprising an aforementioned feature (e.g., “the” feature), it is intended that the element not be limited to one and only one of the feature described merely by the incidental use of the definite article.

Furthermore, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

While particular embodiments of the present invention have been shown and described, it will be obvious to those skilled in the art that, based upon the teachings herein, various modifications, alternative constructions, and equivalents may be used without departing from the invention claimed herein. Consequently, the appended claims encompass within their scope all such changes, modifications, etc. as are within the true spirit and scope of the invention. Furthermore, it is to be understood that the invention is solely defined by the appended claims. The above description is not intended to present an exhaustive list of embodiments of the invention. Unless expressly stated otherwise, each example presented herein is a nonlimiting or nonexclusive example, whether or not the terms nonlimiting, nonexclusive or similar terms are contemporaneously expressed with each example. Although an attempt has been made to outline some exemplary embodiments and exemplary variations thereto, other embodiments and/or variations are within the scope of the invention as defined in the claims below.

1. A method of providing first and second output signals in response to first and second input signals, comprising:
providing the first and second input signals at complementary logic states;
providing first and second intermediate signals on first and second nodes at the complementary logics states in response to the providing the first and second input signals at the complementary logic states;
providing a first clocked inverter having a signal input coupled to the first node, a signal output coupled to the second node, and a clock input;
providing a second clocked inverter having a signal input coupled to the second node, a signal output coupled to the first node, and a clock input;
providing the first and second input signals at a predetermined one of the complementary logic states after providing the first and second input signals at the complementary logic states;
enabling the clock inputs of the first and second clocked inverters prior to providing the first and second input signals at the predetermined one of the complementary logic states whereby the first and second intermediate signals at the complementary logic states are latched; and
providing the first and second output signals responsive to the first and second intermediate signals.

2. The method of claim 1, wherein the first and second clocked inverters have second clock inputs, further comprising enabling said second clock inputs in response to providing the first and second input signals at the complementary logic states.

3. The method of claim 1, wherein the first and second clocked inverters are characterized as inverting only one of the complementary logic states when the clock inputs are disabled and inverting both complementary logic states when the clock inputs are enabled.

4. The method of claim 1, wherein providing the first and second intermediate signals is achieved by third and fourth clocked inverters responsive to the first and second input signals.

5. The method of claim 4, wherein the third and fourth clocked inverters are characterized as inverting only one of the complementary logic states when the clock inputs are disabled and inverting both complementary logic states when the clock inputs are enabled.

6. A method of providing first and second output signals in response to first and second input signals, comprising:
providing the first and second input signals at complementary logic states;
providing first and second intermediate signals on first and second nodes at the complementary logics states in response to the providing the first and second input signals at the complementary logic states;
providing a first clocked inverter having a signal input coupled to the first node, a signal output coupled to the second node, and a clock input;
providing a second clocked inverter having a signal input coupled to the second node, a signal output coupled to the first node, and a clock input;
providing the first and second input signals at a predetermined one of the complementary logic states during a precharge phase;
enabling the clock inputs of the first and second clocked inverters in response to entering the precharge phase; and
providing the first and second output signals responsive to the first and second intermediate signals.

7. The method of claim 6, wherein the first and second inverters have second clock inputs, further comprising enabling said second clock inputs in response to providing the first and second input signals at the complementary logic states.

8. The method of claim 6, wherein providing the first and second intermediate signals is achieved by third and fourth clocked inverters responsive to the first and second input signals.

9. The method of claim 8, wherein the third and fourth clocked inverters are characterized as inverting only one of the complementary logic states when the clock inputs are disabled and inverting both logic states when the clock inputs are enabled.

10. A circuit, comprising:
a first clocked inverter having a signal input for receiving a first input signal, a clock input responsive to a clock signal, and an output;
a second clocked inverter having a signal input for receiving a second input signal, a clock input responsive to the clock signal, and an output;
a third clocked inverter having a signal input coupled to the output of the first clocked inverter, a clock input responsive to the clock signal, and an output;
a fourth clocked inverter having a signal input coupled to the output of the second clocked inverter, a clock input responsive to the clock signal, and an output, wherein the output of the fourth clocked inverter is coupled to the input of the third clocked inverter and the output of the third clocked inverter is coupled to the input of the fourth clocked inverter.

11. The circuit of claim 10 further comprising:
a first inverter having an input coupled to the output of the first clocked inverter and an output for providing a first output signal; and
a second inverter having an input coupled to the output of the second clocked inverter and an output for providing a second output signal.

12. The circuit of claim 10, wherein the first clocked inverter comprises:
a first transistor having a control electrode coupled for receiving the first input signal, a first current electrode coupled to a first power supply terminal, and a second current electrode;
a second transistor having a control electrode coupled for receiving the first input signal, a first current electrode coupled to the second current electrode of the first transistor, and a second current electrode; and
a third transistor having a control electrode coupled to be responsive to the clock signal, a first current electrode coupled to the second current electrode of the second transistor, and a second current electrode coupled to a second power supply terminal.

13. The circuit of claim 12, wherein the third clocked inverter comprises:
a fourth transistor having a control electrode coupled to the second current electrode of the first transistor, a first current electrode coupled to the second power supply terminal, and a second current electrode coupled to the output of the second clocked inverter;
a fifth transistor having a control electrode coupled to the second current electrode of the first transistor, a first current electrode coupled to the second current electrode of the fourth transistor, and a second current electrode; and
a sixth transistor having a control electrode coupled to be responsive to the clock signal, a first current electrode coupled to the second current electrode of the fifth transistor, and a second current electrode coupled to the first power supply terminal.

14. The circuit of claim 13, wherein the third and fourth transistors are P channel transistors.

15. The circuit of claim 10, wherein the first clocked inverter comprises:
a first transistor having a control input for receiving the first signal, a first current electrode coupled to a first power supply terminal, and a second current electrode coupled to the signal input of the third clocked inverter;
a second transistor having a control input for receiving the clock signal, a first current electrode coupled to the second current electrode of the first transistor, and a second current electrode; and
a third transistor having a control electrode for receiving a control signal, a first current electrode coupled to the second current electrode of the second transistor, and a second current electrode coupled to a second power supply terminal.

16. A circuit, comprising:
a first inverting circuit having a signal input for receiving a first input signal and an output;
a second inverting circuit having a signal input for receiving a second input signal and an output;
a first clocked inverter having a signal input coupled to the output of the first inverting circuit, a clock input responsive to a clock signal, and an output; and
a second clocked inverter having a signal input coupled to the output of the second inverting circuit, a clock input responsive to the clock signal, and an output;

17. The circuit of claim 16, wherein the first clocked inverter comprises:.
a first transistor having a control electrode coupled to the output of the first inverting circuit, a first current electrode coupled to a first power supply terminal, and a second current electrode;
a second transistor having a control electrode coupled to the output of the first inverting circuit, a first current electrode coupled to the second current electrode of the first transistor, and a second current electrode; and
a third transistor having a control electrode coupled to be responsive to the clock signal, a first current electrode coupled to the second current electrode of the second transistor, and a second current electrode coupled to a second power supply terminal.

18. The circuit of claim 16, wherein the first inverting circuit is further characterized as having a clock input and wherein the first inverting circuit comprises:
a first transistor having a control electrode coupled for receiving the first input signal, a first current electrode coupled to a first power supply terminal, and a second current electrode;
a second transistor having a control electrode coupled for receiving the first input signal, a first current electrode coupled to the second current electrode of the first transistor, and a second current electrode; and
a third transistor having a control electrode coupled to be responsive to the clock signal, a first current electrode coupled to the second current electrode of the second transistor, and a second current electrode coupled to a second power supply terminal.

19. The circuit of claim 16, wherein the first inverting circuit is further characterized as having a clock input and wherein the first inverting circuit comprises:
a first transistor having a control electrode for receiving the first signal, a first current electrode coupled to a first power supply terminal, and a second current electrode coupled to the signal input of the first clocked inverter;
a second transistor having a control input for receiving the clock signal, a first current electrode coupled to the second current electrode of the first transistor, and a second current electrode; and
a third transistor having a control electrode for receiving a control signal, a first current electrode coupled to the second current electrode of the second transistor, and a second current electrode coupled to a second power supply terminal.

20. The circuit of claim 19, further comprising:
a first inverter having an input for receiving a first primary input signal and an output for providing the first input signal;
a second inverter having an input for receiving a second primary input signal and an output for providing the second input signal; and
a logic gate having a first input for receiving the first primary input signal, a second input for receiving the second input signal, and an output for providing the control signal.

21. The circuit of claim 16, further comprising:
a first inverter having an input coupled to the output of the first clocked inverter and an output for providing a first output signal; and
a second inverter having an input coupled to the output of the second clocked inverter and an output for providing a second output signal.

22. A circuit comprising a domino-compatible latch, the latch comprising:
complementary input inverters;
input control circuitry coupled to the input inverters to selectively configure the input inverters to prevent an output of each input inverter from making a first signal transition type;
cross-coupled storage inverters, each storage inverter having an input coupled to receive a signal from an output of one of the input inverters; and
storage control circuitry coupled to selectively configure the storage inverters to prevent an output of each storage inverter from making a second signal transition type.

23. The circuit of 22 wherein the first transition type is a transition from low to high.

24. The circuit of 22 wherein the second transition type is a transition from high to low.

25. The circuit of 22 wherein the first transition type is a transition from a first signal level corresponding to a first power rail value to a second signal level corresponding to a second power rail value and the second transition type is a transition from the second signal level to the first signal level.

26. A latch comprising:
a clocked input stage coupled to receive first and second complementary input signals;
a clocked storage stage coupled to the clocked input stage, the clocked storage stage comprising two cross-coupled inverters, wherein each of the invertors are clocked. an output stage coupled to the clocked storage stage to provide first and second complementary output signals.
